(19) United States
(12) Patent Application Publication
(10) Pub. No.: US 2008/0220553 A1
(43) Pub. Date: Sep. 11, 2008

(54) Method of producing liquid crystal display device including forming an align mark in an insulating mother substrate

(76) Inventors: Myung-il PARK, Daejeon (KR); Min-jae KO, Cheonan-si (KR); Dong-chin LEE, Cheonan-si (KR)

Correspondence Address: Frank Chau, Esq.;F. CHAU & ASSOCIATES, LLC, 130 Woodbury Road, Woodbury, NY, 11797, US

(21) Appl. No.: 11/931,206

(22) Filed: Oct. 31, 2007

(30) Foreign Application Priority Data
Mar. 6, 2007 (KR) 10-2007-0021875

(51) Int. Cl. H01L 21/02

(52) U.S. Cl. 438/30; 257/E21.536

(57) ABSTRACT

A method of producing a liquid crystal display in which elements can be precisely aligned includes: providing an insulating mother substrate; forming an align mark within the insulating mother substrate by irradiating laser light, which has a wavelength less than 355 nm and having an insulating mother substrate absorbance of 10% or greater for the laser light; forming a plurality of elements with reference to the align mark on the insulating mother substrate; and forming a plurality of insulating unit substrates by cutting the insulating mother substrate.

This application claims priority under 35 U.S.C. § 119 to Korean Patent Application No. 10-2007-0021875, filed on Mar. 6, 2007, the contents of which are herein incorporated by reference in their entirety.

### BACKGROUND OF THE INVENTION

1. Technical Field

The present disclosure is directed generally to a liquid crystal display device, and more particularly to a method of producing a liquid crystal display device in which a plurality of elements have been precisely aligned on a substrate.

2. Description of the Prior Art

A liquid crystal display (LCD) is one of the most widely used flat panel displays, and includes two substrates having electrodes thereon and a liquid crystal layer interposed between the substrates. The liquid crystal display controls the amount of light passing through the liquid crystal layer by applying a voltage to the electrodes to rearrange liquid crystal molecules of the liquid crystal layer.

Among various liquid crystal displays, a liquid crystal display having the two substrates, each of which is provided with a separate field-generating electrode, is generally used. One of the two substrates (i.e., a thin-film transistor substrate) is provided with wirings including a plurality of pixel electrodes, which are arranged in a matrix form, and the other substrate (i.e., a common electrode substrate) is provided with one common electrode covering the entire surface of the other substrate. In such a liquid crystal display, an image is displayed by applying a separate voltage to each pixel electrode.

To form a plurality of wirings including pixel electrodes on one substrate through patterning and to form a common electrode on the other substrate through patterning, a photolithography process is generally used. However, since the photolithography process includes a large number of processes including a photoresist applying process, an exposing process using a photo mask, a developing process, an etching process, a photoresist stripping process, etc., the photolithography process requires a lengthy processing time and numerous and complex processing facilities. In addition, a high material cost is required when a liquid crystal display is produced by means of the photolithography process.

To reduce the manufacturing cost for a liquid crystal display, various methods of forming a plurality of wirings on a substrate by other means, such as an ink-jet method, a laser patterning method, etc. are being studied. However, since such methods do not use a photo mask, it is difficult to precisely align a plurality of wirings with each other, so that the liquid crystal display may have a pixel defect, a defect in an aperture ratio, and so on. Particularly, when an element, such as a color filter pattern, is additionally formed on the substrate in which thin-film transistor elements have been formed, it is more difficult to precisely align not only the wirings but also the other elements, so that the possibility of occurrence of the aforementioned defects further increases.

### SUMMARY OF THE INVENTION

Embodiments of the present invention provide a liquid crystal display with a high accuracy in alignment. Other embodiments of the present invention are not be limited to the above aspect, and those skilled in the art will appreciate other aspects of the present invention from the following description.

According to an embodiment of the invention, there is provided a method of producing a liquid crystal display, the method including: providing an insulating mother substrate; forming an align mark within the insulating mother substrate by irradiating laser light, which has a wavelength less than 355 nm and having an insulating mother substrate absorbance of 10% or greater for the laser light; forming a plurality of elements with reference to the align mark on the insulating mother substrate; and forming a plurality of insulating unit substrates by cutting the insulating mother substrate.

According to an embodiment of the invention, there is also provided a method of producing a liquid crystal display, the method including: providing an insulating mother substrate; forming at least one align mark within the insulating mother substrate by irradiating pulsed laser light which has a wavelength of 355 nm or greater and a pulse width within a range from 10⁻¹⁵ to 10⁻¹² second; forming a plurality of elements on the insulating mother substrate with reference to the align mark; and forming a plurality of insulating unit substrates by cutting the insulating mother substrate.

Other detailed aspects of the present invention are included in the following detailed description and the accompanying drawings.

### BRIEF DESCRIPTION OF THE DRAWINGS

The above and other aspects and features of embodiments of the present invention will be more apparent from the following detailed description taken in conjunction with the accompanying drawings.

FIGS. 1 to 4 are views illustrating steps of a method of producing a liquid crystal display according to an embodiment of the present invention.

FIG. 5 is a graph illustrating a correlation between the transmittance of the mother substrate and the wavelengths of laser light used in the embodiment of FIGS. 1 to 4.

FIGS. 6 to 8 are views illustrating steps of a method of producing a liquid crystal display according to an embodiment of the present invention.

### DETAILED DESCRIPTION OF THE EXEMPLARY EMBODIMENTS

Features of embodiments of the present invention, and methods for achieving them will be apparent to those skilled in the art from the detailed description of the embodiments together with the accompanying drawings. The scope of the present invention is not limited to the embodiments disclosed in the specification and the present invention can be realized in various types. Like numbers refer to like elements throughout. It will be understood that when an element or layer is referred to as being “on,” “connected to” or “coupled to” another element or layer, it can be directly on, connected to or coupled to the other element or layer or intervening elements or layers may be present.

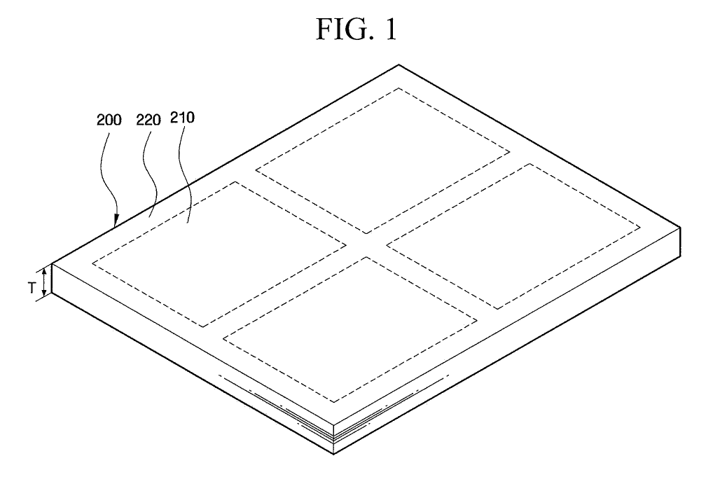

Hereinafter, a method of producing a liquid crystal display according to an embodiment of the present invention will be described in detail with reference to FIGS. 1 to 5. FIGS. 1 to 4 are views illustrating steps of a method of producing a liquid crystal display according to this embodiment of the present invention.

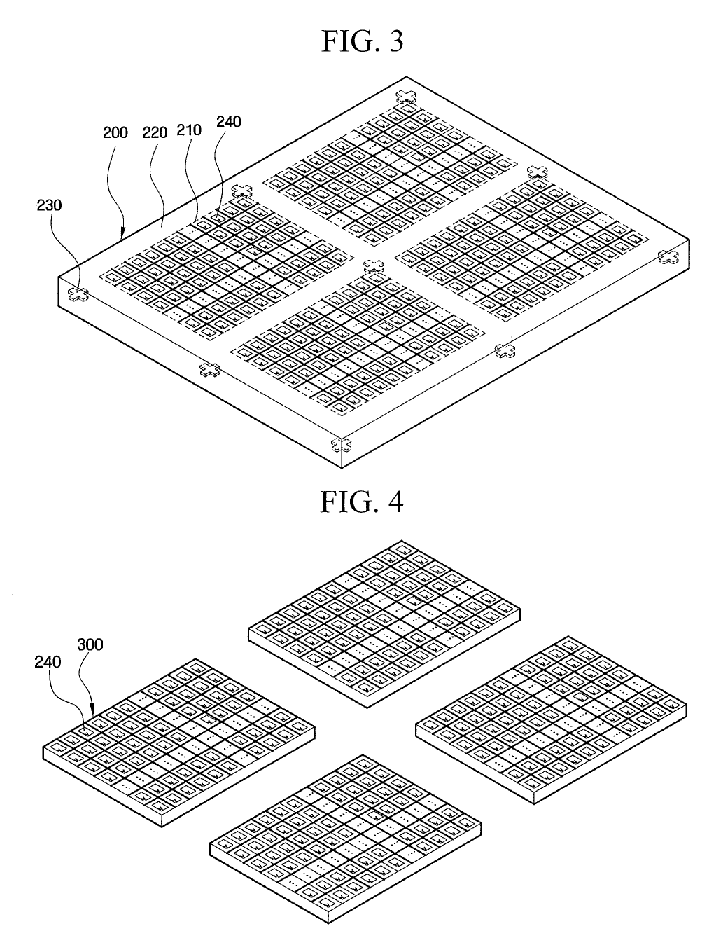

First, referring to FIG. 1, an insulating mother substrate 200 is disposed on a substrate supporting plate (not shown). The insulating mother substrate 200 is made of light-transmitting material, for example, glass. The insulating mother substrate 200 includes a plurality of active regions 210 and a dummy region 220, in which a plurality of elements (see reference numeral “240” in FIG. 3) are formed in the active regions 210, and the dummy region 220 is disposed between the active regions 210 and is provided with an align mark (see reference numeral “230” in FIG. 3) therein. That is, since a plurality of elements are formed on each active region 210, and each active region 210 becomes an insulating unit substrate (see reference numeral “300” in FIG. 4) through the following processes, a plurality of insulating unit substrates may be produced from one insulating mother substrate 200. The insulating mother substrate 200 has a predetermined thickness “T,” for example, a thickness of 0.7 mm.

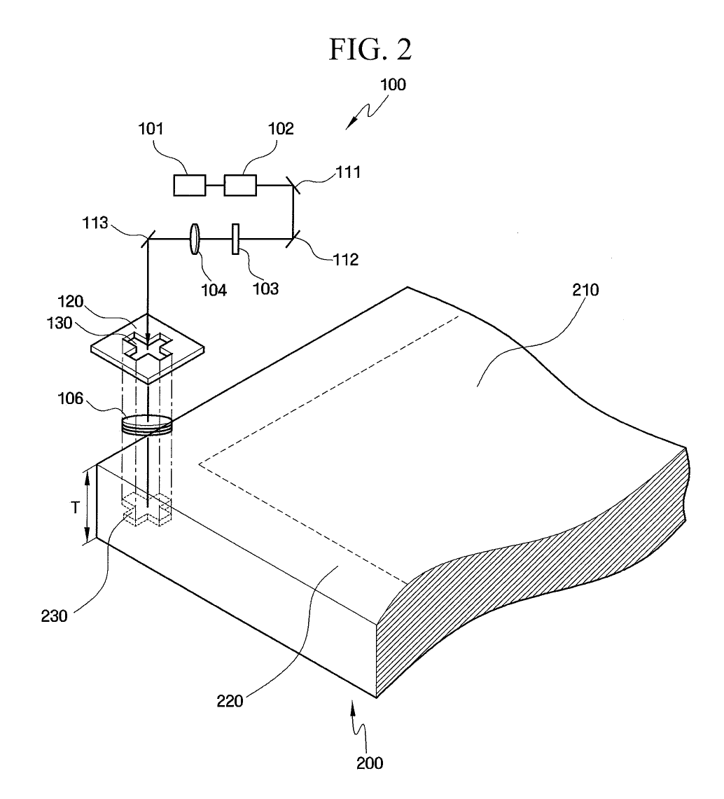

Then, referring to FIG. 2, laser light is irradiated into the insulating mother substrate 200 by means of a laser apparatus 100, thereby forming the align mark 230.

The laser apparatus 100 causes raw laser light, which has been emitted from a laser source 101, to pass through an attenuator 102, a homogenizer 103 and a field lens 104, thereby controlling and converging the energy of the laser light.

The laser apparatus 100 according to an embodiment of the present invention can irradiate laser light onto the insulating mother substrate 200 having an absorbance of 10% or greater for the laser light. If the insulating mother substrate 200 has a high transmittance for the laser light, most of the laser light irradiated into the insulating mother substrate 200 passes through the insulating mother substrate 200, so that it becomes impossible to pattern a predetermined shape in the insulating mother substrate 200. Therefore, to form an intended align mark 230 in the insulating mother substrate 200, the amount of laser light passing through the insulating mother substrate 200 must be small. In other words, the insulating mother substrate 200 has a high absorbance for the laser light. Generally, for laser light to be absorbed by the insulating mother substrate 200 and to form the align mark 230, it is necessary for the insulating mother substrate 200 to have a laser light absorbance of 10% or greater. In other words, it is necessary for the insulating mother substrate 200 to have a laser light transmittance of less than 90%. Laser light having such a transmittance may have a UV wavelength less than 355 nm, preferably, a UV wavelength equal to or less than 266 nm.

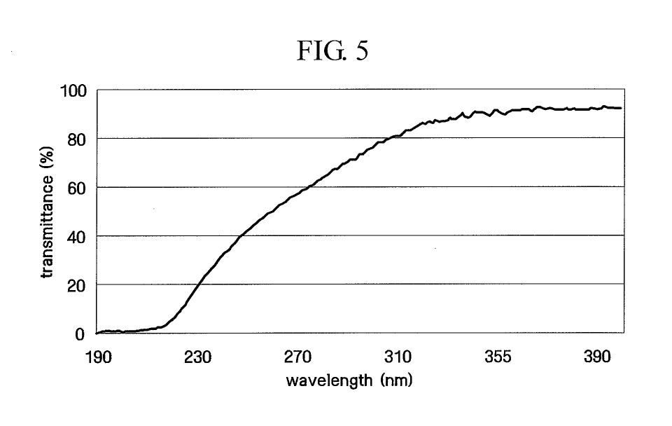

Hereinafter, laser light transmittances of the insulating mother substrate 200 according to an embodiment of the present invention for wavelengths of laser light will now be described with reference to FIGS. 2 and 5. FIG. 5 is a graph illustrating a correlation between the transmittance of the mother substrate and the wavelengths of laser light used in this embodiment of the present invention.

As shown in FIGS. 2 and 5, when laser light irradiated into the insulating mother substrate 200 has a wavelength less than 355 nm, the laser light transmittance of the insulating mother substrate 200 becomes less than about 90%. In other words, when laser light has a wavelength equal to or greater than 355 nm, most of the laser light passes through the insulating mother substrate 200, so that it is impossible to form the align mark 230. In contrast, the insulating mother substrate 200 absorbs about 10% or greater of laser light having a wavelength less than 355 nm, so that when laser light having such a wavelength is irradiated into the insulating mother substrate 200, the align mark 230 can be formed within the insulating mother substrate 200. Particularly, if laser light has a UV wavelength of 266 nm or less, the insulating mother substrate 200 has an absorbance of 50% or greater for the laser light, so that such laser light enables the align mark 230 to be easily formed into the insulating mother substrate 200. Such laser apparatus 100 according to an embodiment of the present invention, which can radiate laser light having a wavelength less than 355 nm, includes an Nd:YAG (Neodymium: Yttrium Aluminum Garnet) laser apparatus, an Nd:YLF (Neodymium: Yttrium Lithium Fluoride) laser apparatus, and an Nd:glass laser apparatus. For example, when the Nd:YAG laser apparatus is used, laser light has a basic wavelength of 1064 nm. In this case, laser light having a wavelength of 266 nm, which can be obtained through wavelength conversion, is irradiated to the insulating mother substrate 200 so as to form the align mark 230. The aforementioned laser apparatuses are priced much lower than an excimer laser apparatus, thereby reducing the cost required to form the align mark 230.

In addition, laser light having a wavelength greater than the aforementioned wavelength may be used to form the align mark 230 in the insulating mother substrate 200. Even when laser light having a wavelength equal to or greater than 355 nm is used, it is possible to form the align mark 230 in the insulating mother substrate 200 by causing a multiphoton absorption phenomenon by means of an ultra-short pulse laser apparatus. The ultra-short pulse laser apparatus may emit laser light having a pulse width within a range from a femto-second to a picosecond, that is, within a range from 10⁻¹⁵ to 10⁻¹² second. Generally, it is only when a photon having energy greater than the ionization energy of an atom is absorbed into the atom that the atom can be excited from a ground state into a transition state. However, when the laser light has a short pulse width as described above, an atom can absorb two or more photons at the same time, so that the atom can be excited from a ground state into a transition state although the atom has absorbed individual photons having energy less than the ionization energy of the atom, which is called a “multiphoton absorption phenomenon.” Accordingly, even when laser light having a long wavelength is irradiated into the insulating mother substrate 200, it is possible to form the align mark 230 in the insulating mother substrate 200. In detail, when laser light having a wavelength equal to or greater than 355 nm and a pulse width within a range from 10⁻¹⁵ to 10⁻¹² second is irradiated, the active region 210 can be formed in the insulating mother substrate 200.

Such an ultra-short pulse laser apparatus includes a Ti:Sapphire laser apparatus, as an appropriate example. When the Ti:Sapphire laser apparatus is used, laser light having an IR wavelength of 800 nm or greater with a pulse width within a range from 10⁻¹⁵ to 10⁻¹² second is irradiated to the insulating mother substrate 200.

Referring again to FIG. 2, laser light is transmitted through a laser mask 120, thereby patterning a predetermined shape. The laser mask 120 is provided therein with a laser mask pattern 130, which has the same shape as that of the align mark 230 to be patterned in the insulating mother substrate 200. Laser light is scanned along the laser mask pattern 130, so that the align mark 230 having the same shape as that of the laser mask pattern 130 is formed in the insulating mother substrate 200.

In this case, the scanning speed and scanning interval of the laser light is determined depending on an internal pattern of the align mark 230. For example, when the internal pattern of the align mark 230 is a hatch pattern, the scanning interval of the laser light may have a high value. In contrast, when the align mark 230 includes a slick and fine line therein, the scanning speed of the laser light may have a low value.

The laser light patterned as described above passes through an object lens 106 so as to form the align mark 230 in an interior location of the insulating mother substrate 200. In this case, the object lens 106 focuses the laser light on the interior location of the insulating mother substrate 200. Accordingly, the align mark 230 is formed in the interior of the insulating mother substrate 200, instead of being formed on the surface of the insulating mother substrate 200. The term “interior location” represents a predetermined location between the upper and lower surfaces of the insulating mother substrate 200, that is, a predetermined location in the direction of thickness thereof. In detail, the align mark 230 may be formed at a portion located between about ⅓ and about ⅔ of the thickness of the insulating mother substrate 200. Although the align mark 230 is formed by removing a part of the insulating mother substrate 200 by the laser light, the surface of the insulating mother substrate 200 is maintained in the same smooth state as before the irradiation of the laser light because the align mark 230 is formed in the interior of the insulating mother substrate 200, instead of being formed on the surface of the insulating mother substrate 200. Accordingly, a plurality of elements formed on the insulating mother substrate 200 in the following processes can be formed in a uniform pattern without a specific portion being recessed or protruded. In addition, when the align mark 230 is formed in the interior of the insulating mother substrate 200, it is possible to prevent glass chipping, surface scratch and any foreign material from occurring in the insulating mother substrate 200 during a post-process of cutting the insulating mother substrate 200.

The align mark 230 is formed in the dummy region (see reference numeral “220” in FIG. 3) of the insulating mother substrate 200. That is, the align mark 230 is disposed between the active regions (see reference numeral “210” in FIG. 3). Since the dummy region is cut and removed in a post-process, the align mark 230 does not negatively effect performance, such as luminance, etc., of a resultant liquid crystal display.

Meanwhile, while the align mark 230 is being formed, the insulating mother substrate 200 is maintained within a temperature range between about 80° C. and about 400° C. so that any defects, such as a crack, a hole, etc., due to a rapid temperature drop after irradiation of the laser light, can be prevented from occurring in the insulating mother substrate 200.

Reference numerals 111, 112 and 113 represent mirrors to adjust the path of the laser light.

The align mark 230 formed through the aforementioned processes may have various shapes, such as a cross shape, a “U” shape, a circle shape, etc. Any shape of the align mark 230 can be used, provided that the shape can provide a basis when a plurality of elements are formed in the post-processes.

Then, referring to FIG. 3, a plurality of elements 240 are formed on the insulating mother substrate 200 with reference to the align mark 230. The plurality of elements 240 are formed by forming a material to constitute each element 240 on the insulating mother substrate 200, aligning an align key (not shown) with reference to the align mark 230 in the interior of the insulating mother substrate 200, and then patterning the material to form each element 240. According to an embodiment of the present invention, the elements 240 may be patterned by using, for example, an ink-jet method or laser projection method. When such methods are used to produce a liquid crystal display, it is possible to reduce the processing time and processing cost, as compared with a photolithography method, which includes a plurality of processes, such as exposing, developing, etching and photoresist stripping.

The elements 240 according to an embodiment of the present invention include metallic wires, which contain gate wires (not shown) and data wires (not shown) laminated in a regular sequence, and may include a black matrix (not shown) and a color filter pattern (not shown).

An example of a process of forming the plurality of elements 240 on the insulating mother substrate 200 by means of the align mark 230 will now be described in detail.

First, a metallic layer (not shown) for gate wiring is laminated on the insulating mother substrate 200, and then, for example, laser light is irradiated to form the align mark 230 on the dummy region 220 of the insulating mother substrate 200, thereby patterning the metallic layer for gate wiring. As a result, the gate wiring, which contains a gate wire, a gate electrode and a sustain electrode, is formed.

Then, a gate insulating layer made of silicon nitride (SiNx) or the like is deposited on the insulating mother substrate 200 and gate wiring, for example, by means of a Chemical Vapor Deposition (CVD) method or the like. Next, an undoped amorphous silicon layer and doped amorphous silicon layer are sequentially deposited on the gate insulating layer, for example, by means of the Chemical Vapor Deposition method or the like, and then a conductive layer for data wiring is deposited, for example, by means of a sputtering method.

Then, laser light according to an embodiment of the present invention is irradiated onto the conductive layer for data wiring, doped amorphous silicon layer and undoped amorphous silicon layer with reference to the align mark 230, thereby forming data wiring, which contains data wires (not shown) and source/drain electrodes (not shown), an ohmic contact layer, and an active layer pattern. In this case, since the data wiring and so on are formed by means of the same align mark 230 as that used for the gate wiring, it is possible to precisely align these wirings with each other.

Next, a passivation layer (not shown) is formed on the active layer pattern and data wiring, and a patterning process is performed by irradiating laser light with reference to the align mark 230, thereby forming a contact hole (not shown) on the passivation layer. Then, conductive material, such as ITO or IZO, for pixel electrodes is deposited on the passivation layer, and is then patterned with reference to the align mark 230, thereby forming pixel electrodes (not shown).

The liquid crystal display produced according to the method of an embodiment of the present invention may have a Color Filter On Array (COA) structure including a color filter pattern and a black matrix, as well as the structure of the aforementioned device 240.

In the case of a process of forming a COA structure, either a black matrix and an ITO electrode or an ITO electrode only is formed on an upper substrate. In this case, after an align mark is formed within an upper glass substrate, an ITO electrode may be formed by using a laser beam or ink-jet projection.

Then, referring to FIGS. 3 and 4, the insulating mother substrate 200, in which a plurality of elements 240 have been formed, is cut to form a plurality of insulating unit substrates 300. Each active region 210 of the insulating mother substrate 200 becomes one insulating unit substrate 300, and the dummy region 220, in which the align mark 230 has been formed, is removed. The insulating unit substrate 300 formed according to the method of the present invention corresponds to a thin-film transistor substrate.

To complete a liquid crystal display, another insulating unit substrate (not shown) is required. Therefore, another insulating mother substrate (not shown) in which a common electrode has been formed is disposed on the insulating mother substrate 200 for the thin-film transistors before cutting of the insulating mother substrate 200, and the two insulating mother substrates are sealed by a sealant and are then cut together, thereby forming the insulating unit substrates 300 for thin-film transistors and the insulating unit substrates for a common electrode, which face each other. Thereafter, liquid crystal is injected between the two insulating unit substrates, thereby forming a liquid crystal panel (not shown).

Finally, a backlight assembly (not shown) including a lamp (not shown) is disposed beneath the liquid crystal panel, and the liquid crystal panel is seated on the backlight assembly, thereby completing the liquid crystal display.

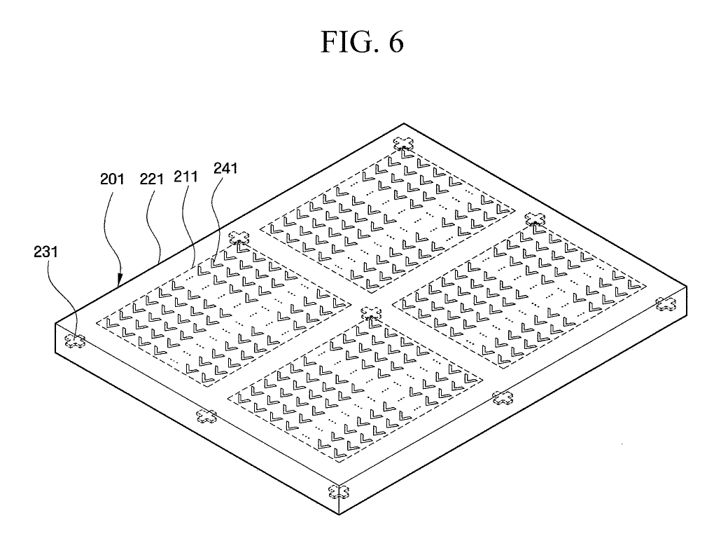

Hereinafter, a method of producing a liquid crystal display according to an embodiment of the present invention will be described with reference to FIGS. 1 and 2 and FIGS. 6 to 8. FIGS. 6 to 8 are views illustrating steps of a method of producing a liquid crystal display according to this embodiment of the present invention. Elements having the same functions as those of the elements which have been previously described will be indicated with the same reference numerals, and a detailed description thereof will be omitted or simplified.

First, through the processes shown in FIGS. 1 and 2, similarly to the aforementioned embodiment of the present invention, laser light is irradiated into an insulating mother substrate (see reference numeral “201” in FIG. 6), thereby forming an align mark (see reference numeral “231” in FIG. 6). To form the align mark 231 according to this embodiment of the present invention, either laser light which has a wavelength less than 355 nm and having an insulating mother substrate absorbance of 10% or greater for the laser light, or laser light which has a wavelength of 355 nm or greater and a pulse width within a range from 10⁻¹⁵ to 10⁻¹² second, is irradiated (shed) into the insulating mother substrate, similarly to the embodiment of FIGS. 2 to 5.

Then, referring to FIG. 6, a plurality of elements 241 are formed on the active regions 211 of the insulating mother substrate 201. The plurality of elements 241 are formed by forming a material to form each element 241 on the insulating mother substrate 201, aligning an align key (not shown) with reference to the align mark 231 formed in a dummy region 221 of the insulating mother substrate 201, and then patterning the material to form each element 241. According to an embodiment of the present invention, the elements 241 may be patterned by using, for example, the ink-jet method or laser projection method, similar to the embodiment described above.

The plurality of elements 241 according to an embodiment of the present invention may include a common electrode formed on top of the insulating mother substrate 201. The common electrode may be formed from conductive common electrode material, which has been formed over the entire surface of the insulating mother substrate 201, or may be formed by patterning such a material. When the common electrode is formed by patterning the conductive material for the common electrode, the patterning is performed with reference to the align mark 231 formed on the insulating mother substrate 201.

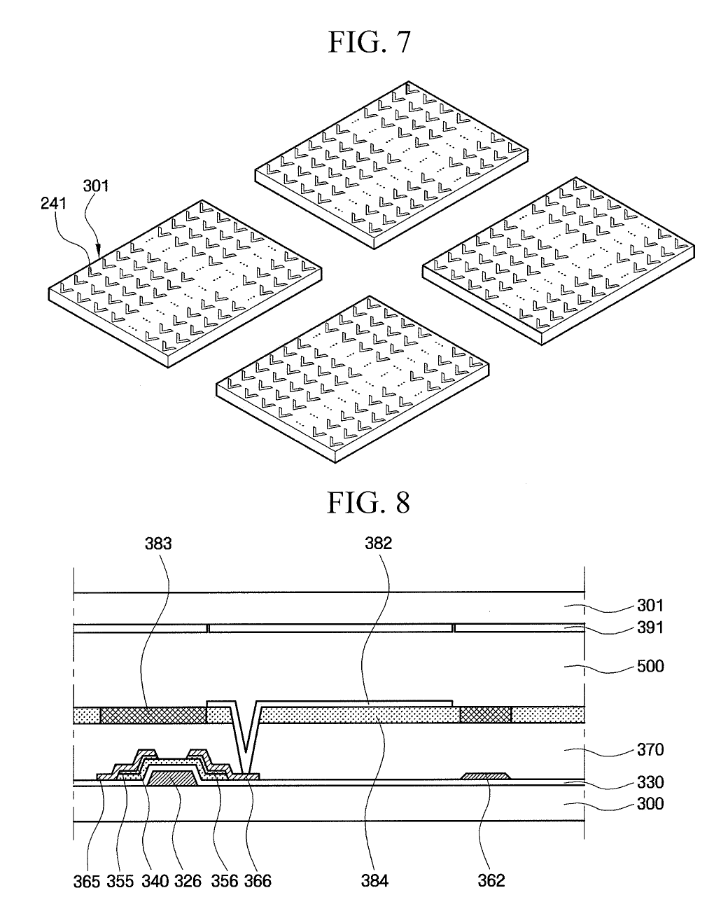

Then, referring to FIGS. 6 and 7, the insulating mother substrate 201, in which the plurality of elements 241 have been formed, is cut to form a plurality of insulating unit substrates 301. The insulating unit substrates 301 are common electrode substrates.

Since a liquid crystal display includes two substrates, a thin-film transistor substrate (not shown) as well as the insulating unit substrate 301 for a common electrode is required to produce the liquid crystal display according to an embodiment of the present invention. To complete the liquid crystal display, an insulating mother substrate for thin-film transistors is disposed beneath the insulating mother substrate 201 for a common electrode before cutting of the insulating mother substrate 201, and the two insulating mother substrates are sealed and then cut together. Then, liquid crystal is injected between an insulating unit substrate for thin-film transistors and an insulating unit substrate 301 for a common electrode, which have been formed as described above, thereby forming a liquid crystal panel.

A liquid crystal display produced by such a manner is shown in FIG. 8.

Referring to FIG. 8, the liquid crystal display includes a liquid crystal panel, which contains an insulating unit substrate for thin-film transistors and an insulating unit substrate for a common electrode.

The insulating unit substrate 300 for thin-film transistors according to the first embodiment of the present invention is provided thereon with a gate electrode 326 to supply a scan signal, a gate insulating layer 330 formed on the gate electrode 326, an active layer pattern 340 formed on the gate insulating layer 330, and ohmic contact layers 355 and 356 improving the contact characteristics of the active layer 340 and source/drain electrodes 365 and 366. In addition, a passivation layer 370 is formed on a data wire 362 and the source/drain electrodes 365 and 366.

In a liquid crystal display of a COA structure, a black matrix 383 is formed on the passivation layer 370 so as to prevent light from leaking. In the pixel region in the black matrix 383, a color filter pattern 384 for blue, green and red is formed for each pixel. In addition, a contact hole is formed on the color filter pattern 384 and passivation layer 370, thereby electrically connecting a pixel electrode 382 and a drain electrode 366, which supply an electric filed to liquid crystal 500.

The liquid crystal display according to an embodiment of the present invention includes the insulating unit substrate 301 for a common electrode, in which a common electrode 391 has been formed. The common electrode 391 according to an embodiment of the present invention may have been patterned in a predetermined shape.

Since all elements required to be patterned are formed through patterning with reference to the align mark (see reference numeral “231” in FIG. 6), the elements are precisely aligned with each other, thereby preventing occurrence of pixel defects in the liquid crystal display.

A backlight assembly including a lamp is disposed beneath the liquid crystal panel formed as above, and the liquid crystal panel is seated on the backlight assembly, thereby completing the liquid crystal display according to this embodiment of the present invention.

As described above, the method of producing a liquid crystal display according to embodiments of the present invention has the following effects.

First, since a low-priced laser apparatus is used to form an align mark within an insulating mother substrate, it is possible to form a reliable align mark at a low cost.

Second, since a plurality of elements on the insulating mother substrate is formed with reference to the align mark, it is possible to improve the accuracy of alignment between the elements.

Third, since an ink-jet method or laser projection method is used to form elements, it is possible to reduce the cost and time required to produce the liquid crystal display.

Although exemplary embodiments of the present invention have been described for illustrative purposes, other embodiments of the present invention are not limited to the exemplary embodiments, and may be produced in various methods. Those skilled in the art will appreciate that various modifications, additions and substitutions are possible, without departing from the scope and spirit of the invention as disclosed in the accompanying claims. Therefore, it should be appreciated that the embodiments described above are not limitative, but only illustrative.

What is claimed is:

1. A method of producing a liquid crystal display, the method comprising:
providing an insulating mother substrate;
forming an align mark within the insulating mother substrate by irradiating laser light, the laser light having a wavelength less than 355 nm, and the insulating mother substrate having a laser light absorbance of 10% or greater;
forming a plurality of elements with reference to the align mark on the insulating mother substrate; and
forming a plurality of insulating unit substrates by cutting the insulating mother substrate.

2. The method of claim 1, wherein the laser light is irradiated by using one of an ND:YAG laser, an Nd:YLF laser and an Nd:glass laser.

3. The method of claim 2, wherein the wavelength corresponds to a UV wavelength of 266 nm or less.

4. The method of claim 1, wherein, while the align mark is being formed, the insulating mother substrate is maintained within a temperature range between about 80° C. and about 400° C.

5. The method of claim 1, wherein the align mark is formed by focusing the laser light on an interior location of the insulating mother substrate.

6. The method of claim 5, wherein the align mark is formed at a portion located between about ⅓ and about ⅔ of a thickness of the insulating mother substrate.

7. The method of claim 1, wherein the insulating mother substrate comprises a plurality of active regions, on which a plurality of elements are formed, and a dummy region disposed between the active regions, in which the align mark is formed.

8. The method of claim 7, wherein the elements are formed by means of an ink-jet method or a laser projection method.

9. The method of claim 8, wherein the elements comprise gate wiring and data wiring, a black matrix and a color filter pattern, which are sequentially laminated on top of the insulating mother substrate.

10. The method of claim 8, wherein the elements comprise a common electrode formed on top of the insulating mother substrate.

11. A method of producing a liquid crystal display, the method comprising:
providing an insulating mother substrate;
forming at least one align mark within the insulating mother substrate by irradiating pulsed laser light which has a wavelength of 355 nm or greater and a pulse width within a range from 10⁻¹⁵ to 10⁻¹² second;
forming a plurality of elements on the insulating mother substrate with reference to the align mark; and
forming a plurality of insulating unit substrates by cutting the insulating mother substrate.

12. The method of claim 11, wherein the laser light is irradiated by using a Ti:Sapphire laser apparatus.

13. The method of claim 12, wherein the wavelength corresponds to an IR wavelength of 800 nm or greater.

14. The method of claim 11, wherein, while the align mark is being formed, the insulating mother substrate is maintained within a temperature range between about 80° C. and about 400° C.

15. The method of claim 11, wherein the align mark is formed by focusing the laser light on an interior location of the insulating mother substrate.

16. The method of claim 15, wherein the align mark is formed at a portion located between about ⅓ to about ⅔ of a thickness of the insulating mother substrate, between an upper surface and a lower surface of the insulating mother substrate.

17. The method of claim 11, wherein the insulating mother substrate comprises a plurality of active regions, on which a plurality of elements are formed, and a dummy region disposed between the active regions, in which the align mark is formed.

18. The method of claim 17, wherein the elements are formed by means of an ink-jet method or a laser projection method.

19. The method of claim 18, wherein the elements comprise gate wiring and data wiring, a black matrix and a color filter pattern, which are sequentially laminated on top of the insulating mother substrate.

20. The method of claim 18, wherein the elements comprise a common electrode formed on top of the insulating mother substrate.
